(19) United States
(12) Patent Application Publication
(10) Pub. No.: US 2009/0165710 A1
(43) Pub. Date: Jul. 2, 2009

(54) MODULE FOR SUPPORTING A SUBSTRATE AND DEPOSITION APPARATUS HAVING THE SAME

(76) Inventors: Young-Min KEE, Cheonan-si (KR); Yang-Soon Kim, Cheonan-si (KR)

Correspondence Address: Haynes and Boone, LLP;IP Section, 2323 Victory Avenue, SUITE 700, Dallas, TX, 75219, US

(21) Appl. No.: 12/187,290

(22) Filed: Aug. 6, 2008

(30) Foreign Application Priority Data
Dec. 28, 2007 (KR) 10-2007-0140532

(51) Int. Cl. B05C 13/00; C23C 14/34

(52) U.S. Cl. 118/503; 204/298.01

(57) ABSTRACT

A module for supporting a substrate includes a frame, a substrate holding unit and a guide mask. The frame receives the substrate including a deposition surface, a rear surface corresponding to the deposition surface, and a side surface connecting the deposition surface with the rear surface. The rear surface is supported by the frame. The substrate holding unit faces the side surface and is combined with a side of the frame. The guide mask includes a guide member and a deposition prevention member. The guide member is combined with the substrate holding unit to cover a portion of the deposition surface. The guide member guides the substrate. The deposition prevention member is combined with the substrate holding unit. The deposition prevention member has greater length than the guiding member to cover the guiding member.

### CROSS-REFERENCE TO RELATED APPLICATIONS

The present application claims priority under 35 U.S.C. §119 to Korean Patent Application No. 10-2007-140532, filed on Dec. 28, 2007 in the Korean Intellectual Property Office (KIPO), the contents of which are herein incorporated by reference in their entirety.

### BACKGROUND OF THE INVENTION

1. Field of the Invention

The present invention relates to a module for supporting a substrate and a deposition apparatus having the module. More particularly, the present invention relates to a module for supporting a substrate to form a thin film pattern and a deposition apparatus having the module.

2. Description of the Related Art

In general, a process for forming a thin film on a substrate is required to manufacture electronic devices such as a liquid crystal display (LCD) device, an organic light-emitting display (OLED) device, a semiconductor device, a compact disc (CD), a hard disk (HD), a MiniDisc (MD), etc.

For example, a sputtering process may be used to manufacture an array substrate that is used for a lower substrate of a display panel of the LCD device. Lines are formed on that array substrate to form an electric circuit through the sputtering process and patterning a metal thin film that is formed by the sputtering process.

A sputtering target is evaporated to form particles, and the particles are deposited on a substrate disposed in a sputtering chamber. A plurality of sputtering chambers may be aligned in series, and different thin films are deposited on the substrate in the different sputtering chambers. The substrate is received in a tray and receives the particles. The substrate may be transported between the sputtering chambers.

In order to improve workability, the tray is aligned in a vertical direction and is inserted into the sputtering chamber through the inline method. In the inline method, the tray is aligned in the vertical direction, and a plurality of processes are performed in series. The substrate that is fixed to the tray is also aligned in the vertical direction, and is deposited through the sputtering process. The particles are irradiated onto the substrate in a direction substantially perpendicular to the vertical direction.

A plurality of clamps are disposed on a peripheral region of the tray. For example, the clamps may be on upper and lower sides of the tray. The clamps open to provide a receiving space of the tray for receiving the substrate, and guide the substrate to prevent the vertically aligned substrate from drifting. Thus, when the thin film is deposited on a surface of the substrate, the thin film is also deposited on the guiding portion of the clamp, which partially covers the surface of the substrate. The deposited thin film grows along the guiding portion of the clamp that covers the surface of the substrate toward a rear surface of the guiding part spaced facing the surface of the substrate.

The substrate aligned in the vertical direction is fixed to the tray, and may become inclined out of a true vertical position due to vibrations during transportation. Therefore, the thin film formed on the guiding portion may be impacted by the substrate, and particles may be generated from the thin film formed on the guiding portion. Defects may be generated on the thin film pattern formed on the surface of the substrate by the particles.

### SUMMARY OF THE INVENTION

The present invention provides a module for supporting a substrate to form a thin film pattern, which is capable of decreasing defects of the substrate.

The present invention also provides a deposition apparatus having the above-mentioned module.

A module for supporting a substrate in accordance with one aspect of the present invention includes a frame, a substrate holding unit and a guide mask. The frame receives the substrate including a deposition surface, a rear surface corresponding to the deposition surface, and a side surface connecting the deposition surface with the rear surface. The rear surface is supported by the frame. The substrate holding unit faces the side surface and is combined with a side of the frame. The guide mask includes a guide member and a deposition prevention member. The guide member is combined with the substrate holding unit to cover a portion of the deposition surface. The guide member guides the substrate. The deposition prevention member is combined with the substrate holding unit. The deposition prevention member has greater length than the guiding member to cover the guiding member.

The substrate holding unit may include a body fixed to the side of the frame, and a rotation part rotating with respect to an externally provided pressure so that a distance between the guide mask and the deposition surface is changed. The rotation part may include a lower portion rotationally combined with the body, and an upper portion holding the guide mask. The body may be combined with the rear surface of the frame, and the rotation part adjacent to the side surface of the substrate may pass through an opening formed through the side of the frame.

The deposition prevention member may be integrally formed with the guiding member, and the deposition prevention member and the guiding member may be combined with the upper portion of the rotation part. Alternatively, the deposition prevention member may be separably combined with the guiding member, and the deposition prevention member and the guiding member may be fixed to the upper portion of the rotation part. The guiding member may include a combining portion fixed to a first side of the upper portion of the rotation part facing the side surface of the substrate, and a guiding portion extended from the combining portion to face the deposition surface, preventing the substrate from being separated from the module. The deposition prevention member may include a holding portion covering a second side of the upper portion corresponding to the first side and combined with the combining portion, and a cover portion extended from the holding portion to face the deposition surface, and covering the guiding portion.

A deposition apparatus in accordance with another aspect of the present invention includes a deposition chamber and a module for supporting a substrate. The deposition chamber deposits a thin film in a direction substantially perpendicular to a gravitational direction through a sputtering process. The module for supporting a substrate includes a frame, a substrate holding unit and a guide mask. The frame supports a rear surface of the substrate that is aligned in a vertical direction substantially parallel with the gravitational direction. The frame is disposed in the deposition chamber. The substrate holding unit is combined with a side of the frame. The substrate holding unit is disposed on the side surface adjacent to upper and lower portions of the substrate. The guide mask including a guide member combined with the substrate holding unit to cover a portion of the deposition surface and guiding the substrate, and a deposition prevention member combined with the substrate holding unit. The deposition prevention member has greater length than the guiding member to cover the guiding member.

The deposition prevention member may include a holding portion fixed to a first side of the substrate holding unit, and a cover portion extended from the holding portion to face the deposition surface to prevent a thin film from being deposited on the guiding member. The guiding member may include a combining portion fixed to a second side of the substrate holding unit facing the first side of the substrate holding unit, and a guiding portion extended between the deposition surface and the cover portion to prevent the substrate from being separated from the module.

The deposition prevention member may be integrally formed with the guiding member, and the deposition prevention member and the guiding member may be combined with the upper portion of the rotation part. Alternatively, the deposition prevention member may be separably combined with the guiding member, and the deposition prevention member and the guiding member may be fixed to the upper portion of the rotation part. The substrate holding unit may include a body, a rotation part and a pressing part. The body is fixed to the side of the frame. The rotation part includes a lower portion rotationally combined with the body, and an upper portion combined with the holding portion and the combining portion. The pressing part is extended from the lower portion. The deposition apparatus may further include a pressing unit that presses the pressing part or is separated from the pressing part to control a distance between the guide mask and the deposition surface so that the substrate is fixed to the frame or is released from the frame. The deposition apparatus may further include a preparation chamber having a pressure substantially the same as an atmospheric pressure, and being disposed adjacent to the deposition chamber. The deposition apparatus may further include a plurality of deposition chambers aligned in series. The deposition apparatus may further include a transportation unit that transports the module receiving the substrate between the preparation chamber and the deposition chambers.

The deposition apparatus may further include a frame mask covering the side of the frame, the frame mask being extended toward a center of the deposition surface to prevent a thin film from being deposited on the side of the frame, the frame mask having a smaller length than the guiding portion.

The frame may be inclined toward the rear surface of the frame with reference to the vertical direction.

According to the module for supporting the substrate and the deposition apparatus having the module of the present invention, particles that may be formed from thin films of an element such as a clamp are prevented to decrease defects of the substrate.

### BRIEF DESCRIPTION OF THE DRAWINGS

The above and other advantages of the present invention will become more apparent in light of the following detailed description of example embodiments thereof with reference to the accompanying drawings, in which:

FIG. 1 is a side view illustrating a deposition apparatus in accordance with one embodiment of the present invention;

FIG. 2 is a top plan view of the deposition apparatus of FIG. 1;

FIG. 3 is a perspective view illustrating a module for supporting a substrate shown in FIG. 1;

FIG. 4 is a cross-sectional view taken along a line I-I′ shown in FIG. 3;

FIG. 5 is a perspective view illustrating a substrate holding unit shown in FIG. 4;

FIG. 6 is a cross-sectional view illustrating the substrate holding unit having an opened frame shown in FIG. 4;

FIG. 7 is a cross-sectional view illustrating a substrate holding unit that holds a substrate shown in FIG. 4;

FIG. 8 is a perspective view illustrating a guide mask shown in FIG. 7;

FIG. 9 is another perspective view illustrating the guide mask shown in FIG. 7;

FIG. 10 is a cross-sectional view illustrating the module for supporting a substrate disposed in a preparation chamber shown in FIG. 1;

FIG. 11 is a cross-sectional view illustrating depositing a thin film on the substrate fixed to the module disposed in the deposition chamber shown in FIG. 1;

FIG. 12 is a cross-sectional view illustrating the module for supporting the substrate on which the thin film is deposited shown in FIG. 1;

FIG. 13 is a cross-sectional view illustrating the substrate separated from the module for supporting the substrate shown in FIG. 1;

FIG. 14 is a cross-sectional view illustrating a deposition apparatus in accordance with another embodiment of the present invention; and

FIG. 15 is a cross-sectional view illustrating a module for supporting a substrate shown in FIG. 14.

### DESCRIPTION OF THE EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention is described in detail with reference to the accompanying drawings.

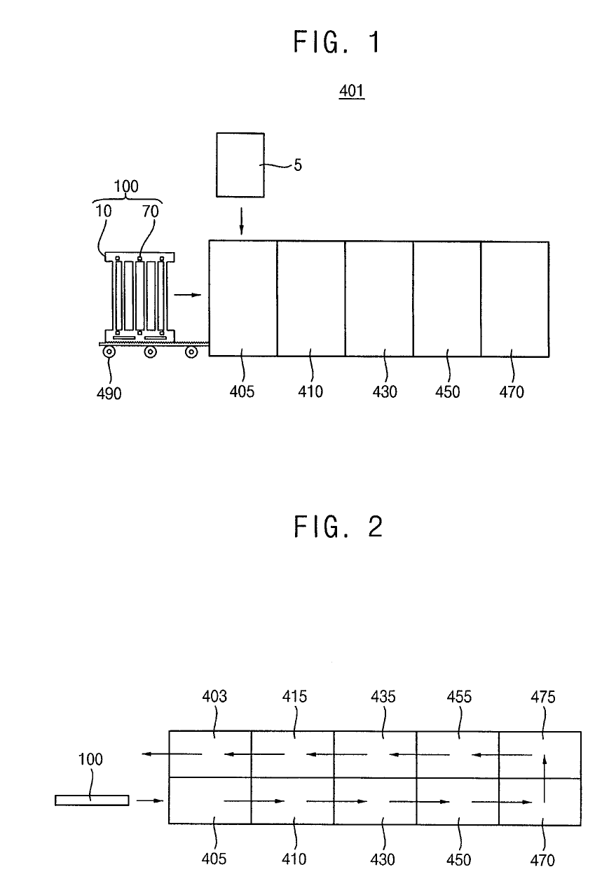

FIG. 1 is a side view illustrating a deposition apparatus in accordance with one embodiment of the present invention. FIG. 2 is a top plan view illustrating the deposition apparatus of FIG. 1.

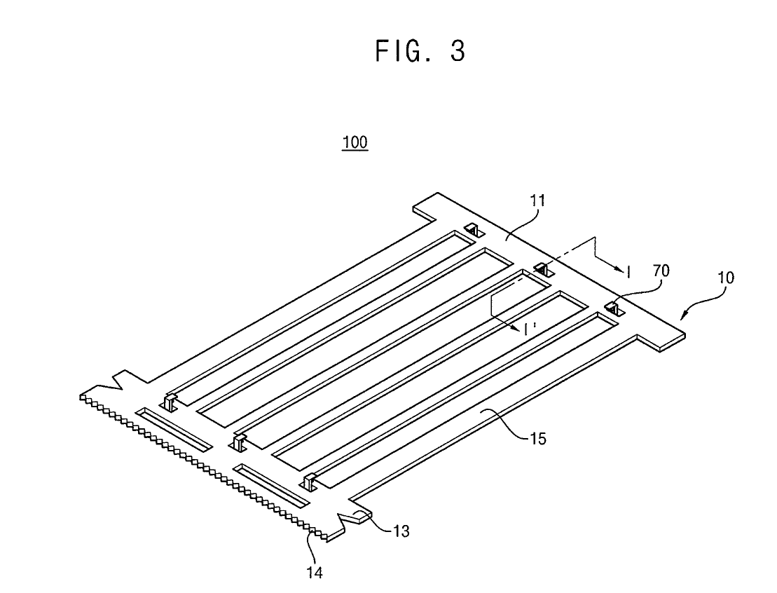

Referring to FIGS. 1 and 2, the deposition apparatus 401 deposits a thin film on a substrate 5. The deposition apparatus 401 includes a deposition chamber 430 and a module 100 for supporting the substrate 5. The module 100 for supporting the substrate 5 is described below with reference to FIGS. 3 to 9.

The thin film may be deposited on a deposition surface 2 of the substrate 5 in the deposition chamber 430 through a sputtering process. The module 100 for supporting the substrate 5 holds the substrate 5 in the deposition chamber 430. Typically an inert gas such as argon (Ar) gas is injected into the deposition chamber 430, and a plasma is generated between a target and the substrate 5, so that particles generated from the target are deposited on the deposition surface 2 of the substrate 5.

The deposition apparatus 401 may include a plurality of deposition chambers 430, 450, 470, 475, 455 and 435 that are aligned in series. Different thin films may be deposited on the deposition surface 2 of the substrate in different deposition chambers 430, 450, 470, 475, 455 and 435, respectively. The deposition chambers 430, 450, 470, 475, 455 and 435 may be aligned in two lines, and the substrate 5 may be introduced into the deposition chambers 430, 450, 470, 475, 455 and 435 in each line.

The deposition apparatus 401 may further include a preparation chamber 405 and a heat treatment chamber 410. The heat treatment chamber 410 is connected to the deposition chamber, and the preparation chamber 405 is connected to the heat treatment chamber 410. The preparation chamber 405 has substantially the same pressure as an atmospheric pressure, and the preparation chamber 405 is mounted in the module 100 for supporting the substrate 5. The heat treatment chamber 410 heats the substrate 5 for preparing the sputtering process.

The deposition apparatus 401 may further include a transportation unit 490 that transports the module 100 for supporting the substrate 5 between the preparation chamber 405, the heat treatment chamber 410 and the deposition chambers 430, 450, 470, 475, 455 and 435. For example, the transportation unit 490 may include a rack unit. A rack rail may be formed on a lower portion of the frame 10. The module 100 for supporting the substrate 5 is aligned in a vertical direction that is substantially parallel with a gravitational direction, and is transported by the transportation unit 490.

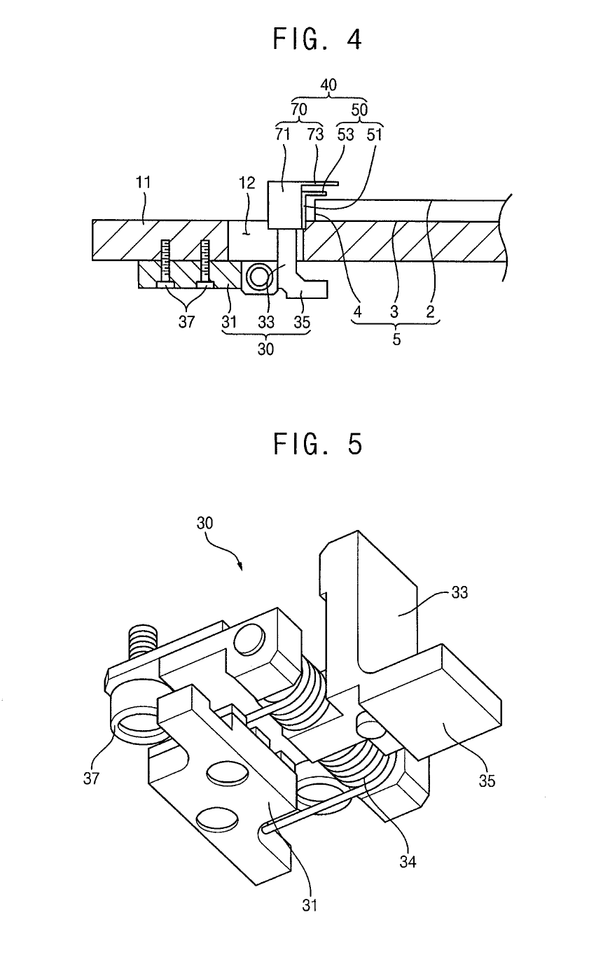

FIG. 3 is a perspective view illustrating a module for supporting a substrate shown in FIG. 1. FIG. 4 is a cross-sectional view taken along a line I-I′ shown in FIG. 3. Referring to FIGS. 3 and 4, the module 100 for supporting the substrate 5 includes the frame 10, a plurality of holding units 30 and a guide mask 40. The module 100 for supporting the substrate 5 supports the substrate 5 during depositing the thin film on the substrate 5.

The frame 10 includes an upper bar 11, a lower bar 13 and a plurality of connecting bars 15. The connecting bars 15 are aligned substantially parallel with each other, and connect the upper bar 11 with the lower bar 13. A plurality of openings 12 are formed through each of the upper bar 11 and the lower bar 13 along a longitudinal direction of each of the upper bar 11 and the lower bar 13.

The substrate 5 has the deposition surface 2, a rear surface 3 and a side surface 4. The thin film is deposited on the deposition surface 2. The rear surface 3 corresponds to the deposition surface 2. The side surface 4 connects the deposition surface 2 with the rear surface 3. The frame 10 supports the rear surface 3 of the substrate 5.

The substrate holding units 30 are connected to sides of the frame 10 and correspond to the side surface 4 of the substrate 5 disposed on the frame 10. For example, the substrate holding units 30 pass through the openings 12 formed through the upper bar 11 and the lower bar 13. The substrate holding unit 30 is combined with the guide mask 40, and controls a distance between the guide mask 40 from the deposition surface 2 of the substrate 5 by an externally provided force.

FIG. 5 is a perspective view illustrating a substrate holding unit shown in FIG. 4.

Referring to FIGS. 4 and 5, the substrate holding unit 30 includes a body 31, a rotation part 33 and a pressing part 35. The body 31 is connected to the rear surface of the upper bar 11 and the lower bar 13 by a screw 37. The rotation part 33 includes a lower portion and an upper portion. For example, the lower portion of the rotation part 33 may be combined with a spring 34 that is fixed to the body 31. The guide mask 40 is combined with the rotation part 33. The upper portion of the rotation part 33 passes through the openings of the upper bar 11 and the lower bar 13, and protrudes from the upper surfaces of the upper bar 11 and the lower bar 13. The pressing part 35 extends from the lower portion of the rotation part 33 to face the rear surface of the frame 10. The pressing part 35 is spaced apart from the rear surface of the frame 10 by a constant distance. When the externally provided force is applied to the pressing part 35, the pressing part 35 and the rotation part 33 rotates with respect to the lower portion of the rotation part 33 as a rotation axis.

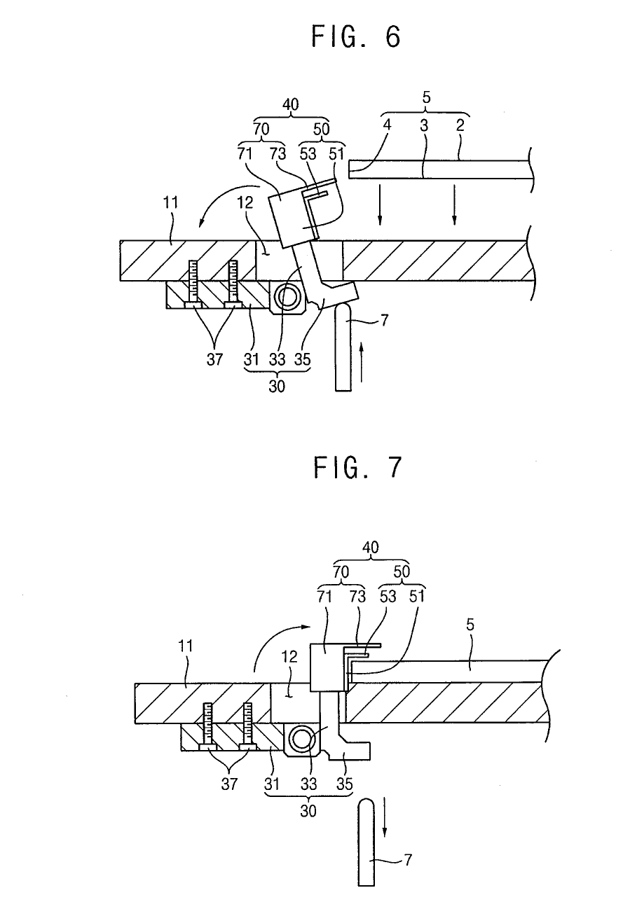

FIG. 6 is a cross-sectional view illustrating the substrate holding unit having an opened frame shown in FIG. 4. FIG. 7 is a cross-sectional view illustrating a substrate holding unit that holds a substrate shown in FIG. 4.

Referring to FIGS. 4, 6 and 7, the guide mask 40 is combined with the substrate holding unit 30 to guide the substrate 5. The guide mask 40 includes a guiding member 50 and a deposition prevention member 70.

In FIG. 4, when an actuator such as a piston 7 (shown in FIGS. 6 and 7) presses the pressing part 35 of the substrate holding unit 30, the rotation part 33 and the guide mask 40 combined with the upper portion of the rotation part 33 rotate so that the rotation part 33 and the guide mask 40 are spaced apart from a center of the frame 10, thereby opening a receiving space of the frame 10 in which the substrate 5 is received.

In FIG. 6, the substrate 5 is introduced into the receiving space of the frame 10. When the rear surface 3 of the substrate 5 is received in the frame 10, the piston 7 is separated from the pressing part 35, and the rotation part 33 and the guide mask 40 rotate in an opposite direction. The guide mask 40 corresponds to a portion of the side of the deposition surface 2 of the substrate 5 to prevent the separation of the substrate 5 from the frame 10.

In FIG. 7, the guiding member 50 guides a corner formed by the deposition surface 2 of the substrate and the side surface 4. A portion of the deposition prevention member 70, which faces the deposition surface 2, is spaced apart from the guiding member 50, and extends to a center of the deposition surface 2 by a length greater than the guiding member 50 to cover the guiding member 50.

The deposition prevention member 70 prevents a thin film from depositing on the guiding member 50 during the depositing of the thin film onto the deposition surface 2 of the substrate 5. Thus, defects caused by particles that are generated from the thin film formed on the guiding member 50 are prevented.

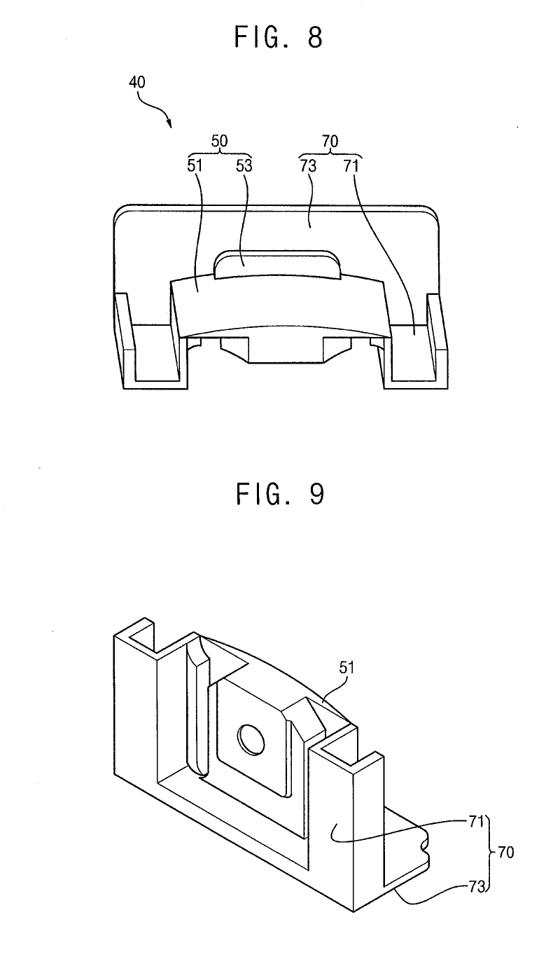

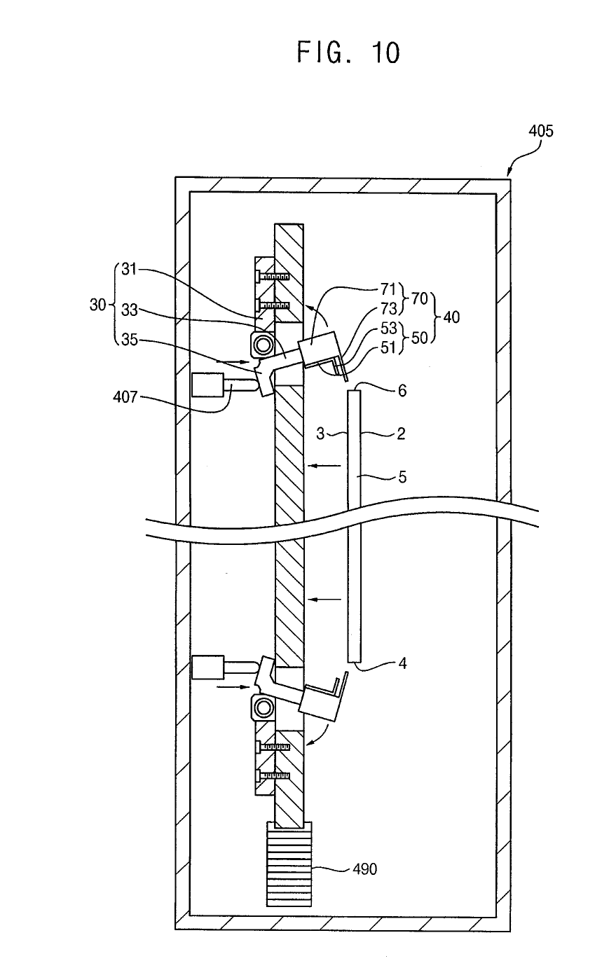

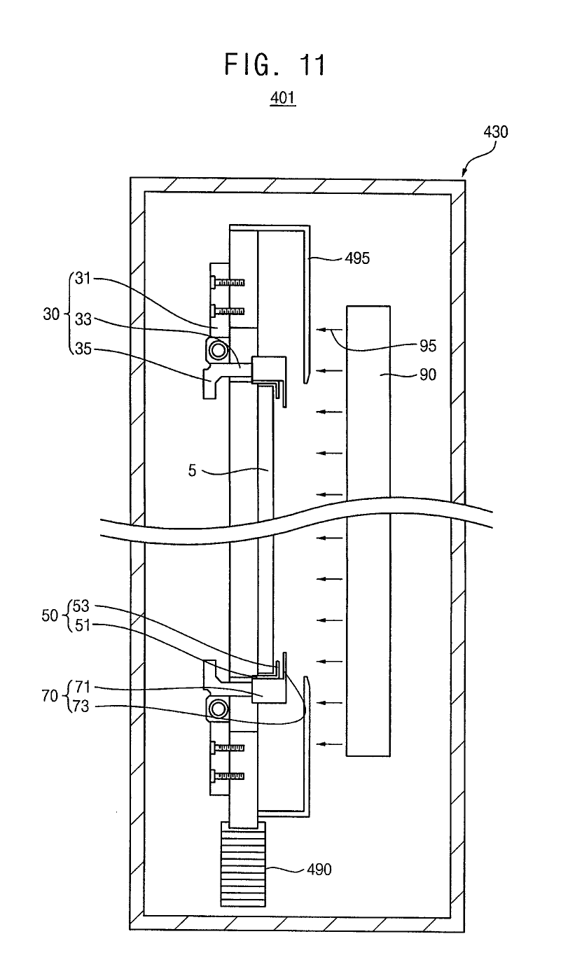

FIG. 8 is a perspective view illustrating a guide mask shown in FIG. 7. FIG. 9 is a perspective view illustrating the guide mask shown in FIG. 7.

Referring to FIGS. 7 to 9, the guiding member 50 is integrally formed with the deposition prevention member 70, and is combined with the upper portion of the rotation part 33.

The guiding member 50 may include a combining portion 51 and the guiding portion 53. The rotation part 33 of the substrate holding unit 30 faces the side surface 4 of the substrate 5.

The combining portion 51 is fixed to a side of the upper portion of the rotation part 33 facing the side surface 4 of the substrate 5. The combining portion 51 is bent along a side corner of the upper end portion to cover a side surface of the upper portion.

The guiding portion 53 extends from an upper edge of the combining portion 51 toward the center of the deposition surface 2 to face the deposition surface 2 of the substrate 5. Thus, the combining portion 51 and the guiding portion 53 form an L-shape. For example, the guiding portion 53 extends toward the center of the deposition surface 2 by a length of about 6 mm to about 7 mm with a width of about 20 mm. The guiding portion 53 may be spaced apart from the deposition surface 2 of the substrate 5 by several millimeters. Although the guiding portion 53 transmits the substrate 5 aligned in the vertical direction or the thin film is deposited on the substrate 5 aligned in the vertical direction, the guiding portion 53 prevents the substrate 5 from being inclined in a direction out of the frame 10.

The deposition prevention member 70 includes a holding portion 71 and a cover portion 73.

The holding portion 71 faces the combining portion 51 of the guiding member 70, and is on the upper portion of the rotation part 33. Thus, the holding portion 71 covers a side surface of the upper portion of the rotation part 33, and is combined with the upper portion. The combining portion 51 is bent at the corner of the upper portion of the rotation part 33, and is connected to the holding portion 71 in a direction substantially perpendicular to the holding portion 71.

The cover portion 73 extends from the upper edge of the holding portion 71 along the upper surface of the upper portion, so that the holding portion 71 and the cover portion 73 form L-shape. The cover portion 73 extends to face the deposition surface 2 of the substrate 5. The cover portion 73 has greater width than the guiding portion 53. For example, the width of the cover portion 73 is about 42 mm. The cover portion 73 has greater length than the guiding portion 53 and extends towards to the center of the deposition surface 2. For example, the length of the cover portion 73 is about 21 mm. The cover portion 73 may be spaced apart from the guiding portion 53 by about 1.5 mm.

When the sputtering process is performed on the deposition surface 2 of the substrate 5 in a direction substantially perpendicular to the deposition surface 2, the thin film may be formed on the entire cover portion 73. When a cover portion makes contact with the guiding portion, the thin film formed on the cover portion 73 may grow toward the rear surface of the cover portion 73 facing the deposition surface 2. However, the cover portion 73 is spaced apart from the guiding portion 53 so that the thin film formed on the cover portion 73 may not extend toward the guiding portion 53. Therefore, although the substrate 5 contacts with the guiding portion 53, the particles may not be generated from the guiding portion 53, so that the defects on the thin film pattern of the substrate 5 caused by the particles may be prevented.

FIG. 10 is a cross-sectional view illustrating the module for supporting the substrate disposed in a preparation chamber shown in FIG. 1.

Referring to FIGS. 8 and 10, the module 100 for supporting the substrate 5 and the substrate 5 are introduced into the preparation chamber 405. For example, the module 100 for supporting the substrate 5 may be inclined toward the rear surface 3 of the substrate 5 by about 3 degrees to about 5 degrees with respect to the vertical direction.

The deposition apparatus 401 may further include a pressing unit 407. The pressing unit 407 may be fixed to the side surface of the preparation chamber 405. The pressing unit 407 presses the substrate holding unit 30 from the rear surface 3 of the module 100 for supporting the substrate 5 that is aligned in the vertical direction. For example, the pressing unit 407 may include a piston to press the pressing part 35 of the substrate holding unit 30.

In FIG. 10, when the piston presses the pressing part 35 of the substrate holding unit 30, the rotation part 33 and the guide mask 40 combined with the upper portion of the rotation part 33 rotate in the direction so that the guide mask 40 is spaced apart from the frame 10, thereby opening the receiving space of the frame 10 for receiving the substrate 5. The substrate 5 is received in the receiving space of the frame 10. When the rear surface 5 of the substrate 5 is received in the frame 10, the piston is separated from the pressing part 35 so that the rotation part 33 and the guide mask 40 rotate in the opposite direction. The guide mask 40 corresponds to a peripheral portion of the deposition surface 2 of the substrate 5 to prevent the substrate 5 being inclined out of the frame 10.

The substrate holding unit 30 and the guide mask 40 combined with the substrate holding unit 30 are disposed on the upper bar and the lower bar of the frame 10. Thus, the side surface 4 of the lower portion of the substrate 5 is supported by the substrate holding unit 30 disposed on the lower bar. Alternatively, the side surface 4 of the lower portion of the substrate 5 may be supported by the combining portion 51 of the guiding member 50. The side surface 6 of the upper portion of the substrate 5 may be spaced apart from the combining portion 51 of the guiding member 50, which is disposed on the upper bar.

FIG. 11 is a cross-sectional view illustrating the depositing of a thin film on the substrate fixed to the module disposed in the deposition chamber shown in FIG. 1.

Referring to FIG. 11, the module 100 for supporting the substrate 5 and the substrate 5 held by the module 100 are aligned in the vertical direction and are introduced into the deposition chambers 430, 450, 470, 475, 455 and 435. For example, a normal direction of the substrate 5 is aligned in the gravitational direction.

After the deposition chamber 430 is evacuated to form a vacuum state, the plasma gas is introduced into the deposition chamber 430. When an electric current is applied to the target and an opposite electrode, the plasma is changed into a plasma state, and the target 90 is sputtered by the plasma particles. The frame 10 of the module 100 for supporting the substrate 5 may function as an opposite electrode of the deposition apparatus. The particles 95 from the target 90 is accelerated by an electric field formed between the substrate 5 and the target 90 in the horizontal direction that is substantially perpendicular to the gravitational direction, thereby being deposited on the deposition surface 2 of the substrate 5.

The deposition apparatus 401 may further include a frame mask 495. The frame mask 495 covers the sides of the module 100 for supporting the substrate 5 to prevent the thin film from being deposited on the sides of the module 100 for supporting the substrate 5. In FIG.11, the frame mask 495 is combined with the side of the module 100 for supporting the substrate 5. For example, the frame mask 495 may be combined with the upper bar and the lower bar of the module 100 for supporting the substrate 5. Therefore, when the module 100 for supporting the substrate 5 is transported by the transportation unit 490, the frame mask 495 is also transported with the module 100 for supporting the substrate 5. Thus, additional frame masks corresponding to the deposition chambers 430, 450, 470, 475, 455 and 435, respectively, may be omitted.

When the rotation part 33 of the substrate holding unit 30 rotates, the frame mask 495 is spaced apart from the guide mask 40 by a predetermined distance so that the rotation of the rotation part 33 is not blocked by the guide mask 40.

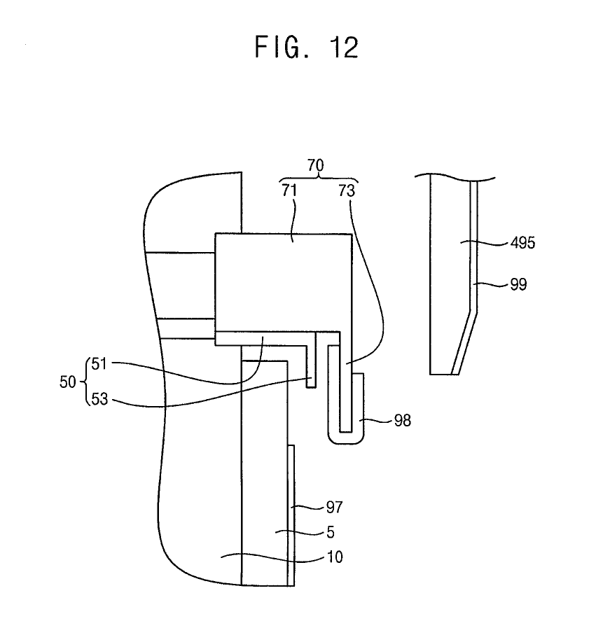

FIG. 12 is a cross-sectional view illustrating the module for supporting the substrate on which the thin film is deposited shown in FIG. 1.

Referring to FIGS. 11 and 12, the frame mask 495 extends toward the center of the deposition surface of the substrate 5 by a distance smaller than the guiding portion 53 of the guiding member 50. The frame mask 495 is spaced apart from the cover portion 373 of the deposition prevention member 70. The frame mask 495 may be spaced apart from the cover portion 373 by about 6 mm to about 7 mm during depositing of the thin film on the substrate 5. When the module 100 for supporting the substrate 5 is transported by the transportation unit 490, the frame mask 495 may be spaced apart from the cover portion 373 by about 15 mm to about 18 mm.

After the deposition process, the thin film pattern 97 is formed on the deposition surface 2 of the substrate. Also, the thin film 98 is formed a front surface of the cover portion 737 of the deposition prevention member 70 except a portion of the cover portion 373, which is blocked by the frame mask 495, and the thin film grows from the front surface of the cover portion 373 toward a rear surface 3 connected to the front surface. When the guiding portion 53 making contact with the substrate 5 is spaced apart from the cover portion 373, the thin film 98 formed on the cover portion 373 may not extend toward the guiding portion 53. A thin film 99 may also be formed on a front surface of the frame mask 495.

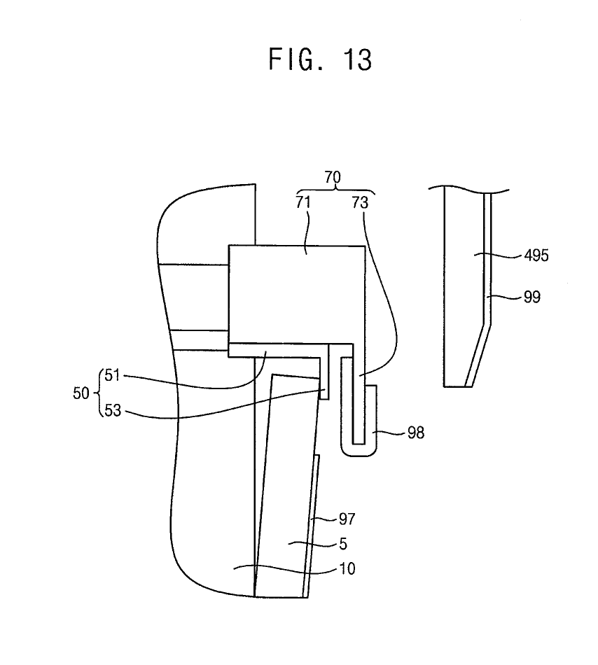

FIG. 13 is a cross-sectional view illustrating the substrate separated from the module for supporting the substrate shown in FIG. 1.

Referring to FIG. 13, the module 100 for supporting the substrate 5 receives the substrate 5, and is aligned in the vertical direction. The vertically aligned module 100 for supporting the substrate 5 is transported into the deposition chambers 430, 450, 470, 475, 455 and 435 by the transportation unit 490. The guiding portion 53 does not press the substrate 5, and prevents the substrate 5 from being separated from the module 100 for supporting the substrate 5. Thus, although the module 100 for supporting the substrate 5 is inclined by the externally provided impact, the substrate 5 may not collide with the guiding portion 53.

According to the present embodiment, the thin film is not formed on the guiding portion 53, so that the defects caused by the particles generated from the thin film on the guiding portion 53 are prevented although the substrate 5 collides with the guiding portion 53.

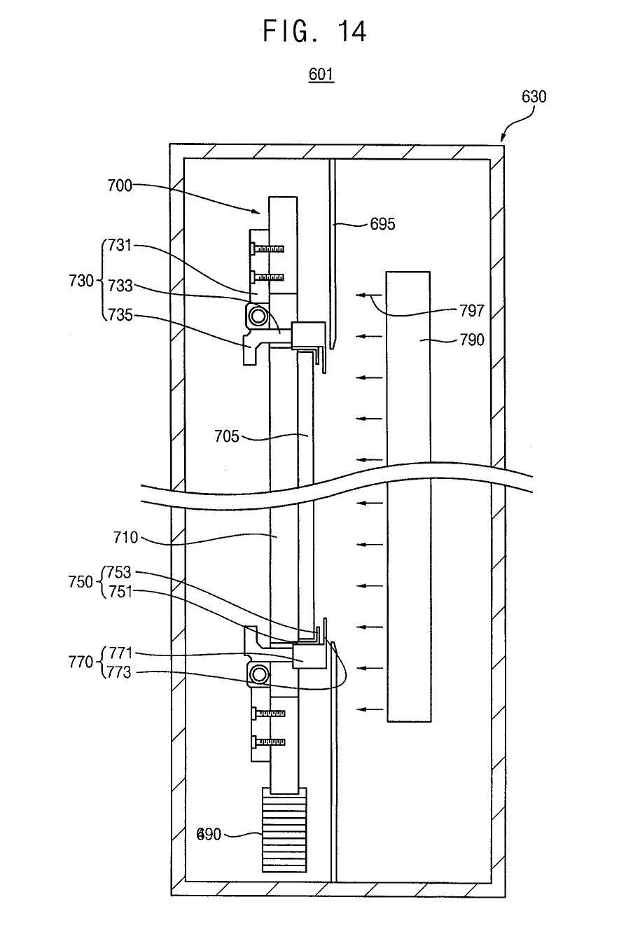

FIG. 14 is a cross-sectional view illustrating a deposition apparatus in accordance with another embodiment of the present invention.

The deposition apparatus 601 of FIG. 14 is substantially the same as the deposition apparatus of FIGS. 8 to 13 except for a module 700 for supporting a substrate and a frame mask 695. Thus, any further repetitive explanation concerning the above elements will be omitted. The deposition apparatus 601 includes a plurality of deposition chambers 630, a module 700 for supporting the substrate, a frame mask 695, a preparation chamber, a heat treatment chamber, a transportation unit 690 and a pressing unit.

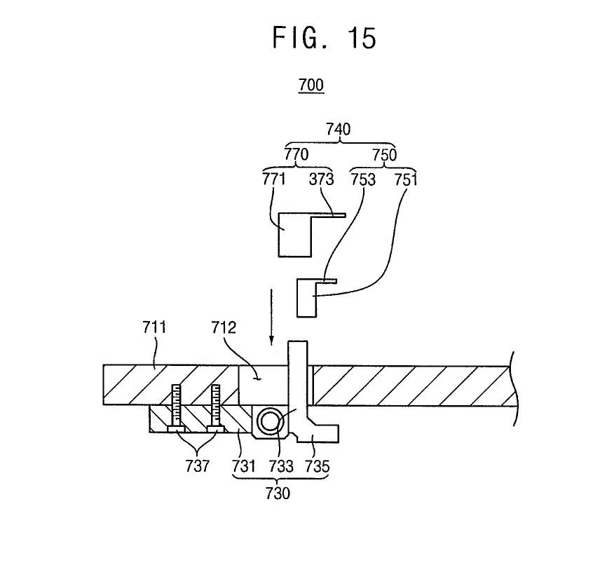

The module 700 for supporting the substrate is explained below with reference to FIG. 15. The module 700 for supporting the substrate includes a frame 710, a plurality of holding units 730 and a guide mask 740. The guide mask 740 includes a guiding member 750 and a deposition prevention member 770. The guiding member 750 is combined with the deposition prevention member 770, and the guiding member 750 and the deposition prevention member 770 are fixed to an upper portion of a rotation part 733 of the substrate holding unit 730. Alternatively, the guiding member 750 may be separable from the deposition prevention member 770.

In FIG. 14, the frame mask 695 is disposed in the deposition chamber 630. Therefore, a plurality of frame masks 695 is disposed in a plurality of deposition chambers, respectively.

The module 700 for supporting the substrate 705 is combined with the substrate 705 in the preparation chamber. Therefore, the rotation part 733 of the substrate holding unit 730 may not rotate in the deposition chamber 630. Therefore, a distance between the frame mask 695 and the guide mask 740 may be decreased compared with the deposition apparatus of FIG. 11.

Therefore, the thin film may not be deposited on the guiding member 750. Also, sputtered particles may not passes through a space between the frame mask 695 and the guiding mask 750 so that the thin film may not be deposited on a side of the frame 710. Thus, defects caused by particles generated from the thin film on the frame 710 may be prevented.

FIG. 15 is a cross-sectional view illustrating a module for supporting a substrate shown in FIG. 14.

The module 700 for supporting the substrate of FIG. 15 is substantially the same as the deposition apparatus of FIGS. 3 to 7 except the guide mask 740. Thus, any further repetitive explanation concerning the above elements will be omitted.

Therefore, the module 700 for supporting the substrate includes the frame 710, the substrate holding units 730 and the guide mask 740.

The guide mask 740 includes the guiding member 750 and the deposition prevention member 770. The deposition prevention member 770 may be separable from the guiding member 750.

The guiding member 750 and the deposition prevention member 770 are combined with each other and are fixed to the upper portion of the rotation part 733. The guiding member 750 and the deposition prevention member 770 of FIG. 15 is substantially the same as the deposition apparatus of FIGS. 6 to 9 except the guiding member 750 may be separable from the deposition prevention member 770. Thus, any further repetitive explanation concerning the above elements will be omitted.

Therefore, the guiding member 750 includes the combining portion 751 and the guiding portion 753, and the deposition prevention member 770 includes the holding portion 771 and the cover portion 373. The location of the combining portion 751, the guiding portion 753, the holding portion 771 and the cover portion 773 with respect to the upper portion of the rotation part 733 and the deposition surface of the substrate is substantially the same as shown in FIGS. 8 and 9, thus any further repetitive explanation concerning the above elements will be omitted.

According to the module for supporting the substrate and the deposition apparatus having the module of the present invention, particles that could be formed from thin films of an element such as a clamp may be prevented from causing defects of the substrate. The module for supporting the substrate and the deposition apparatus having the module may be used for manufacturing a liquid crystal display (LCD) device, an organic light-emitting display (OLED) device, a semiconductor device, a compact disc (CD), a hard disk (HD), a MiniDisc (MD), etc.

This invention has been described with reference to the example embodiments. It is evident, however, that many alternative modifications and variations will be apparent to those having skill in the art in light of the foregoing description. Accordingly, the present invention embraces all such alternative modifications and variations as falling within the spirit and scope of the appended claims.

What is claimed is:

1. A module for supporting a substrate comprising:
a frame receiving the substrate, the substrate including a deposition surface, a rear surface opposite the deposition surface, and a side surface connecting the deposition surface with the rear surface, wherein the frame supports the rear surface;
a substrate holding unit facing the side surface and being combined with a side of the frame; and
a guide mask including:
a guiding member combined with the substrate holding unit to cover a portion of the deposition surface, the guide member guiding the substrate; and
a deposition prevention member combined with the substrate holding unit, the deposition prevention member having a length greater than a length of the guiding member to cover the guiding member.

2. The module of claim 1, wherein the substrate holding unit comprises:
a body fixed to the side of the frame; and
a rotation part rotatable in response to an externally provided force so that a distance between the guide mask and the deposition surface is changed, the rotation part including:
a lower portion rotationally combined with the body; and
an upper portion holding the guide mask.

3. The module of claim 2, wherein the deposition prevention member is integrally formed with the guiding member, and the deposition prevention member and the guiding member are combined with the upper portion of the rotation part.

4. The module of claim 2, wherein the guiding member comprises:
a combining portion fixed to a first side of the upper portion of the rotation part facing the side surface of the substrate; and
a guiding portion extended from the combining portion to face the deposition surface, the guiding portion preventing the substrate from being separated from the module.

5. The module of claim 2, wherein the deposition prevention member comprises:
a holding portion covering a second side of the upper portion corresponding to the first side, and being combined with the combining portion; and
a cover portion extended from the holding portion to face the deposition surface, the cover portion covering the guiding portion.

6. The module of claim 2, wherein the deposition prevention member is separably combined with the guiding member, and the deposition prevention member and the guiding member are fixed to the upper portion of the rotation part.

7. The module of claim 2, wherein the body is combined with the rear surface of the frame, and the rotation part adjacent to the side surface of the substrate passes through an opening formed through the side of the frame.

8. A deposition apparatus comprising:
a deposition chamber that deposits a thin film in a direction substantially perpendicular to a gravitational direction through a sputtering process; and
a module for supporting a substrate including:
a frame supporting a rear surface of the substrate that is aligned in a vertical direction substantially parallel with the gravitational direction, the frame being disposed in the deposition chamber;
a substrate holding unit combined with a side of the frame, the substrate holding unit being disposed on the side surface adjacent to upper and lower portions of the substrate; and
a guide mask including a guide member combined with the substrate holding unit to cover a portion of the deposition surface and guiding the substrate, and a deposition prevention member combined with the substrate holding unit, the deposition prevention member having greater length than the guiding member to cover the guiding member.

9. The deposition apparatus of claim 8, wherein the deposition prevention member comprises:
a holding portion fixed to a first side of the substrate holding unit; and
a cover portion extended from the holding portion to face the deposition surface to prevent a thin film from being deposited on the guiding member.

10. The deposition apparatus of claim 9, wherein the guiding member comprises:
a combining portion fixed to a second side of the substrate holding unit facing the first side of the substrate holding unit; and
a guiding portion extended between the deposition surface and the cover portion to prevent the substrate from being separated from the module.

11. The deposition apparatus of claim 10, wherein the deposition prevention member is integrally formed with the guiding member, and the deposition prevention member and the guiding member are combined with the upper portion of the rotation part.

12. The deposition apparatus of claim 10, wherein the deposition prevention member is separably combined with the guiding member, and the deposition prevention member and the guiding member are fixed to the upper portion of the rotation part.

13. The deposition apparatus of claim 10, wherein the substrate holding unit comprises:
a body fixed to the side of the frame;
a rotation part including:
a lower portion rotationally combined with the body; and
an upper portion combined with the holding portion and the combining portion; and
a pressing part extended from the lower portion.

14. The deposition apparatus of claim 13, further comprising a pressing unit that presses the pressing part or is separated from the pressing part to control a distance between the guide mask and the deposition surface so that the substrate is fixed to the frame or is released from the frame.

15. The deposition apparatus of claim 14, further comprising a preparation chamber having a pressure substantially the same as an atmospheric pressure, and being disposed adjacent to the deposition chamber.

16. The deposition apparatus of claim 15, further comprises a plurality of deposition chambers aligned in series.

17. The deposition apparatus of claim 16, further comprising a transportation unit that transports the module receiving the substrate between the preparation chamber and the deposition chambers.

18. The deposition apparatus of claim 10, further comprising a frame mask covering the side of the frame, the frame mask being extended toward a center of the deposition surface to prevent a thin film from being deposited on the side of the frame, the frame mask having a smaller length than the guiding portion.

19. The deposition apparatus of claim 8, wherein the frame is inclined toward the rear surface of the frame with reference to the vertical direction.
